(19) United States
(12) Patent Application Publication
(10) Pub. No.: US 2020/0031661 A1
(43) Pub. Date: Jan. 30, 2020

(54) LIQUID PROOF PRESSURE SENSOR

(71) Applicant: InvenSense, Inc., San Jose, CA (US)

(72) Inventors: Calin MICLAUS, Fremont, CA (US); Matthias SCHMIDT, Munich (DE); Vijay WAKHARKAR, Los Gatos, CA (US); Milena VUJOSEVIC, San Jose, CA (US); Manish SHARMA-KULAMARVA, Chandler, AZ (US)

(21) Appl. No.: 16/520,228

(22) Filed: Jul. 23, 2019

Related U.S. Application Data
(60) Provisional application No. 62/702,856, filed on Jul. 24, 2018.

(51) Int. Cl. B81B 7/00; G01L 9/00; G01L 19/06

(52) U.S. Cl. CPC B81B 7/0058; B81B 7/0061; B81B 7/007; B81B 2207/015; G01L 19/06; B81B 2201/0264; B81B 2207/098; G01L 9/0041

(57) ABSTRACT

A device includes a sensor die, an electrical coupling, a substrate, and a housing unit. The sensor die is coupled to the substrate via the electrical coupling. The housing unit and the substrate are configured to house the sensor die and the electrical coupling. The housing unit comprises an opening that exposes the sensor die to an environment external to the housing unit. The housing unit may include a drainage configured to drain liquid, e.g., water, oil, etc., out from an interior environment of the housing unit to the environment external to the housing unit. In some embodiments the housing unit comprises a membrane barrier exposing the sensor die to an environment external to the housing unit while preventing liquid from the environment external to enter an interior environment of the housing unit. It is appreciated that in some embodiments, the membrane barrier may be porous and may be ePTFE.

### RELATED APPLICATIONS

The instant application is non-provisional patent application and claims the benefit and priority to a U.S. Provisional Application 62/702,856 filed on Jul. 24, 2018, which is incorporated herein by reference in its entirety.

### BACKGROUND

Many electronic devices are used in various conditions and are exposed to different external environments. For example, sensors may come in contact with the external environment such as water, gas, etc., that may be damaging to the sensing device. Conventionally, the package cavity of the electronic device is increased and filled with gel to protect the electronic device from exposure to external liquid and gas.

Filling the package cavity with gel protects the electronic device, but it fails to address the additional offset that is created when water liquids enters the electronic device.

### SUMMARY

Accordingly, a need has arisen to protect the electronic device from being exposed to the external environment, e.g., water, gas, etc., with reduced offset impact. Moreover, a need has arisen to remove unwanted liquid from the interior of the electronic device out and/or to prevent the unwanted liquid from entering the electronic device. Accordingly, in some embodiments, a sensor die is provided wherein the package cavity is filled with gel. In some embodiments, the electronic device may include a mechanism to remove the unwanted liquid or channel the unwanted liquid away from the interior environment of the electronic device to its exterior environment, thereby reducing the offset impact of the unwanted liquid. In some embodiments, the electronic device may include a membrane barrier that is configured to prevent unwanted liquid from entering the interior cavity, e.g., package cavity, of the electronic device.

In some embodiments, a device includes a sensor die, an electrical coupling, a substrate, and a housing unit. The sensor die is coupled to the substrate via the electrical coupling. The housing unit and the substrate are configured to house the sensor die and the electrical coupling. The housing unit comprises an opening that exposes the sensor die to an environment external to the housing unit. The housing unit further comprises a drainage configured to drain liquid out from an interior environment of the housing unit to the environment external to the housing unit. In some embodiments, the device may further include a gel filled within the interior environment of the housing unit covering the sensor die and the substrate. The gel is configured to protect the sensor die, the electrical coupling, and the substrate from exposure to the liquid. The gel is selected from a group consisting of silicone and fluoro silicone. In some embodiments, the gel is thick enough to cover the sensor die and the electrical coupling. The drainage is configured to drain the liquid deposited over the gel surface. In some embodiments, the drainage is positioned on a horizontal wall of the housing unit that is positioned at a lowest liquid collection point and the substrate. In some embodiments, the drainage is positioned on a vertical wall of the housing unit that is positioned at a lowest liquid collection point and the substrate. According to some embodiments, the device further includes a channel connected to the drainage to channel the liquid out from the interior environment of the housing unit to the environment external to the housing unit. It is appreciated that the sensor die comprises MEMS-CMOS. In one illustrative example, the sensor die is a pressure sensor.

In some embodiments, a device includes a sensor die, an electrical coupling, a substrate, and a housing unit. The sensor die is coupled to the substrate via the electrical coupling. The housing unit and the substrate are configured to house the sensor die and the electrical coupling. The housing unit comprises a membrane barrier that exposes the sensor die to an environment external to the housing unit. The membrane barrier is further configured to prevent liquid, e.g., water, oil, etc., from the environment external to the housing unit to enter an interior environment of the housing unit. In some embodiments, the device further includes a gel filled within the interior environment of the housing unit covering the sensor die and the substrate. The gel is configured to protect the sensor die, the electrical coupling, and the substrate from exposure to the liquid. The gel is selected from a group consisting of silicone and fluoro silicone. In some embodiments, the gel is thick enough to cover the sensor die and the electrical coupling. The membrane barrier is porous according to some embodiments. According to one embodiment, the membrane barrier is ePTFE. It is appreciated that the device may further include a drainage within the housing that is configured to drain liquid out from the interior environment of the housing unit to the environment external to the housing unit. The sensor die may be a MEMS-CMOS and it may include a pressure sensor.

These and other features and aspects of the concepts described herein may be better understood with reference to the following drawings, description, and appended claims.

### BRIEF DESCRIPTION OF DRAWINGS

FIGS. 1A-1B show a sensor die device in accordance with some embodiments.

FIGS. 2A-2D show a sensor device with a horizontal drainage mechanism in accordance with some embodiments.

FIGS. 3A-3C show a sensor device with a vertical drainage mechanism in accordance with some embodiments.

FIG. 4 shows a sensor device with a membrane barrier in accordance with some embodiments.

### DETAILED DESCRIPTION

Before various embodiments are described in greater detail, it should be understood by persons having ordinary skill in the art that the embodiments are not limiting, as elements in such embodiments may vary. It should likewise be understood that a particular embodiment described and/or illustrated herein has elements which may be readily separated from the particular embodiment and optionally combined with any of several other embodiments or substituted for elements in any of several other embodiments described herein.

It should also be understood by persons having ordinary skill in the art that the terminology used herein is for the purpose of describing the certain concepts, and the terminology is not intended to be limiting. Unless indicated otherwise, ordinal numbers (e.g., first, second, third, etc.) are used to distinguish or identify different elements or steps in a group of elements or steps, and do not supply a serial or numerical limitation on the elements or steps of the embodiments thereof. For example, “first,” “second,” and “third” elements or steps need not necessarily appear in that order, and the embodiments thereof need not necessarily be limited to three elements or steps. It should also be understood that, unless indicated otherwise, any labels such as “left,” “right,” “front,” “back,” “top,” “middle,” “bottom,” “forward,” “reverse,” “clockwise,” “counter clockwise,” “up,” “down,” or other similar terms such as “upper,” “lower,” “above,” “below,” “vertical,” “horizontal,” “proximal,” “distal,” and the like are used for convenience and are not intended to imply, for example, any particular fixed location, orientation, or direction. Instead, such labels are used to reflect, for example, relative location, orientation, or directions. It should also be understood that the singular forms of “a,” “an,” and “the” include plural references unless the context clearly dictates otherwise.

Unless defined otherwise, all technical and scientific terms used herein have the same meaning as commonly understood by persons of ordinary skill in the art to which the embodiments pertain.

Accordingly, a need has arisen to protect the electronic device from being exposed to the external environment, e.g., water, oil, and other liquids, with reduced offset impact. Moreover, a need has arisen to remove unwanted liquid from the interior of the electronic device and/or to prevent the unwanted liquids from entering the electronic device. Accordingly, in some embodiments, a sensor die, e.g., an integrated micro-electro-mechanical system (MEMS)-complementary metal-oxide-semiconductor (CMOS), with reduced height is provided wherein the package cavity is filled with gel. In other embodiments, the sensor die could include MEMS die or a MEMS die bonded to a CMOS die. In yet other embodiments, the package could comprise discrete CMOS die electrically connected to sensor die.. In some embodiments, the electronic device may include a mechanism to remove the unwanted liquid or channel the unwanted liquid away from the interior environment of the electronic device to its exterior environment, thereby reducing the offset impact of the unwanted liquid. In some embodiments, the electronic device may include a membrane barrier that is configured to prevent unwanted liquid from entering the interior cavity, e.g., package cavity, of the electronic device.

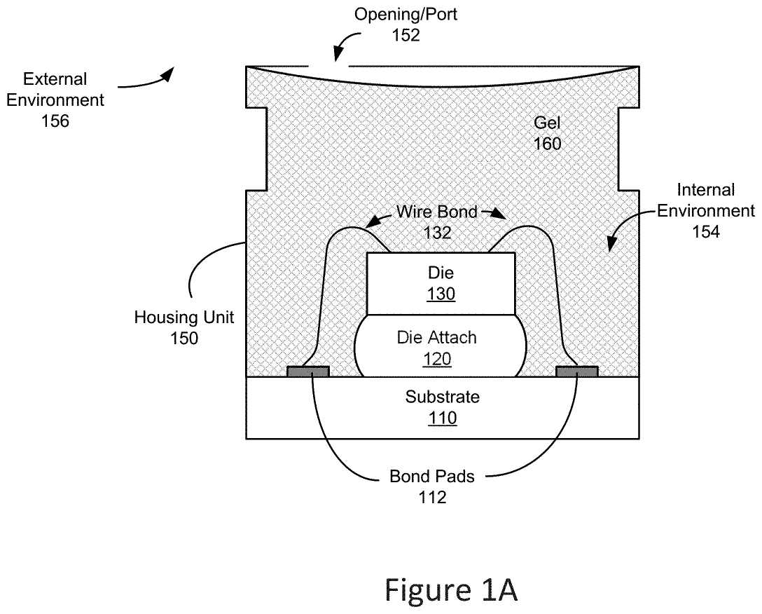

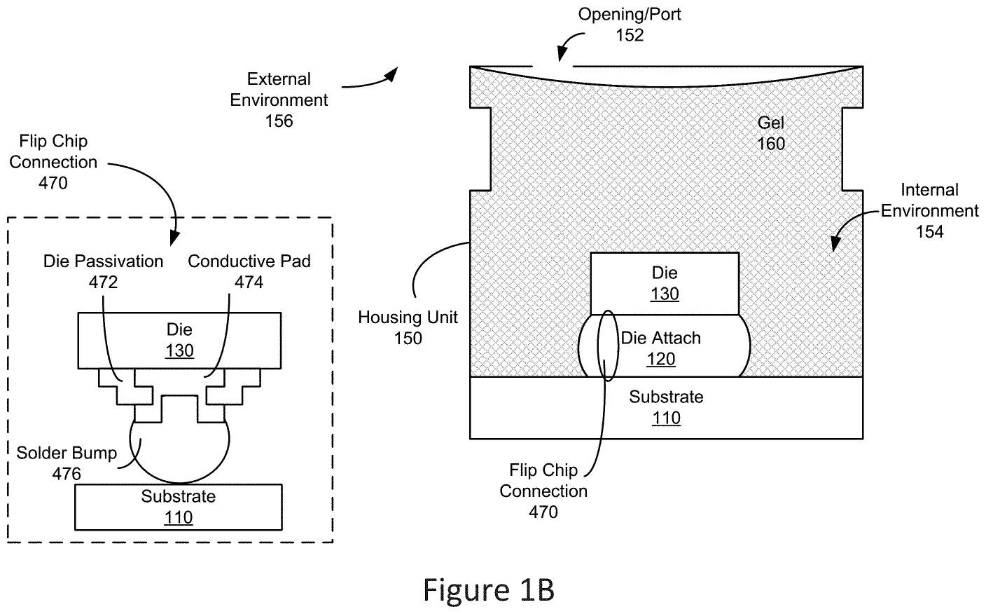

FIGS. 1A-1B show a sensor die device in accordance with some embodiments. The device includes a substrate 110 and a die 130 that is attached to the substrate 110 using a die attach material 120. Die attach material 120 provides mechanical attachment. Die attach material 120 may be any one of e.g., soft adhesive, soft silicon glue, RTV, epoxy, etc. In some embodiments the substrate can be a PCB or similar package substrate. It is appreciated that in some embodiments, the die 130 may be electrically coupled to the substrate 110 using electrical coupling. The die 130 may be a sensor, e.g., pressure sensor, temperature sensor, microphone sensor, etc. It is appreciated that according to some embodiments the die 130 is a sensor die comprising MEMS. In this embodiment, the electrical coupling is via wire bond 132 that electrically couples the die 130 to the bond pads 112 positioned on the substrate 110. The housing unit 150 may be attached to the substrate 110 to form a housing for the die 130. In some embodiments, the housing unit 150 is attached to the substrate 110 via attach material, e.g., solder, epoxy glue, etc. The housing unit 150 may include an opening 152 that exposes the die 130 to the external environment 156 of the device even though the die 130 is positioned within the internal environment 154 of the housing unit 150. It is appreciated that in some embodiments, the housing unit 150 may be a packaging container for housing the electronic components, e.g., sensor, die, etc., therein.

It is appreciated that in order to protect the device and electronic components within from the external environment, e.g., liquid such as water or oil, gas,etc., the internal environment 154 may be filled with gel 160, e.g., silicone and fluoro silicone. It is appreciated that the gel may be a pressure transmitting dielectric.

It is appreciated that in the illustrated embodiment, the housing unit 150 coupled to the substrate 110 forms a housing for the electronic components therein. However, it is appreciated that in some embodiments, the housing unit 150 may further house and hold the exterior surfaces, e.g., bottom surface, side surfaces, etc., of the substrate 110 (not shown here).

Referring now to FIG. 1B, the device similar to that of FIG. 1A is shown. In FIG. 1B, the die 130 is coupled to the substrate using flip chip connection instead of wire bonds 132. In this embodiment, the die 130 may be a flip chip and electrically and mechanically connected to the substrate through die attach 120. More specifically the flip chip connection 470 connects the die 130 to the substrate 110. In some embodiments, the flip chip connection 470 includes a conductive pad 474 for electrically connecting the die 130 to the substrate 110. A die passivation layer 472 overlays the die 130 and the conductive pad 474. Solder bumps 476 are formed over the conductive pad 474. Optionally, die attach 120 can include mechanical attachment such as RTV or other soft material in addition to solder balls. FIG. 1B is similar to FIG. 1A except that the housing unit 150 houses at least some of the exterior surfaces of the substrate 110, e.g., bottom surface, side surfaces, or any combination thereof, etc. In this embodiment, the housing unit 150 along with the die 130, die attach 120, and the gel 160 encapsulates the substrate 110.

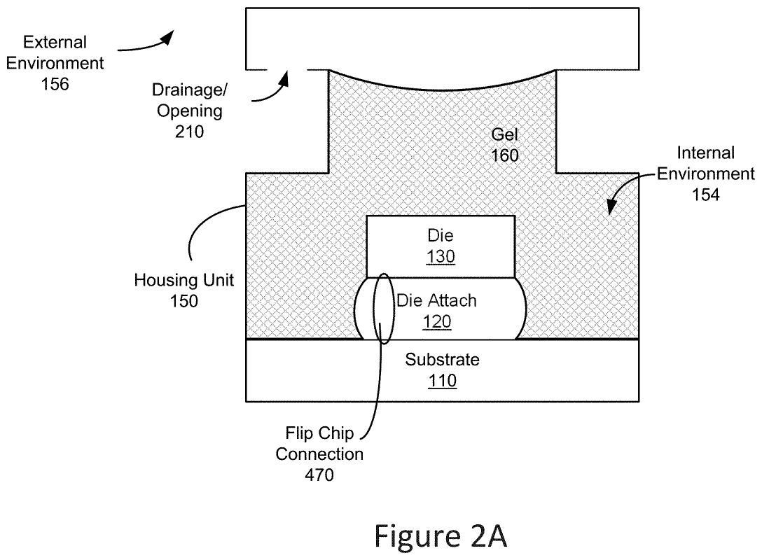

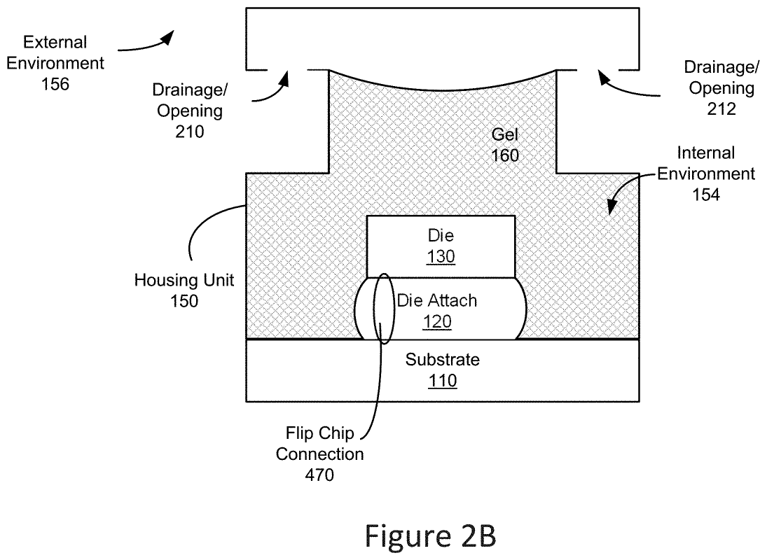

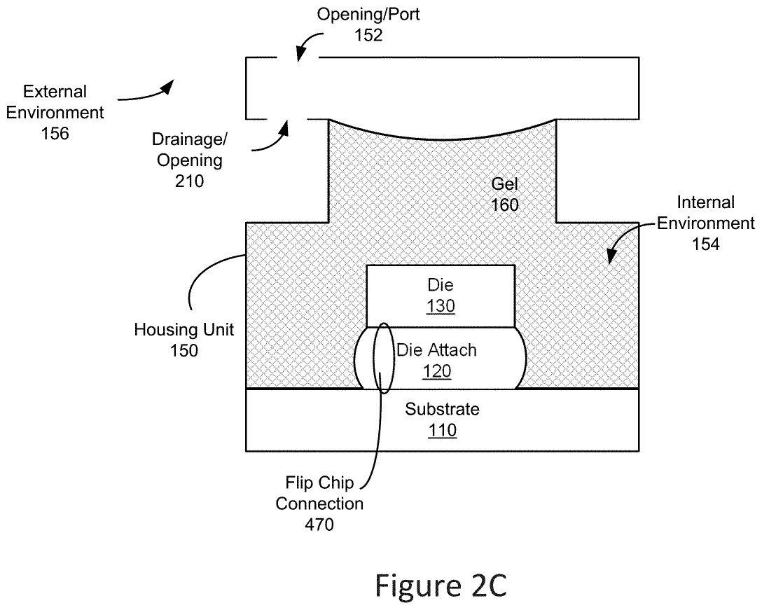

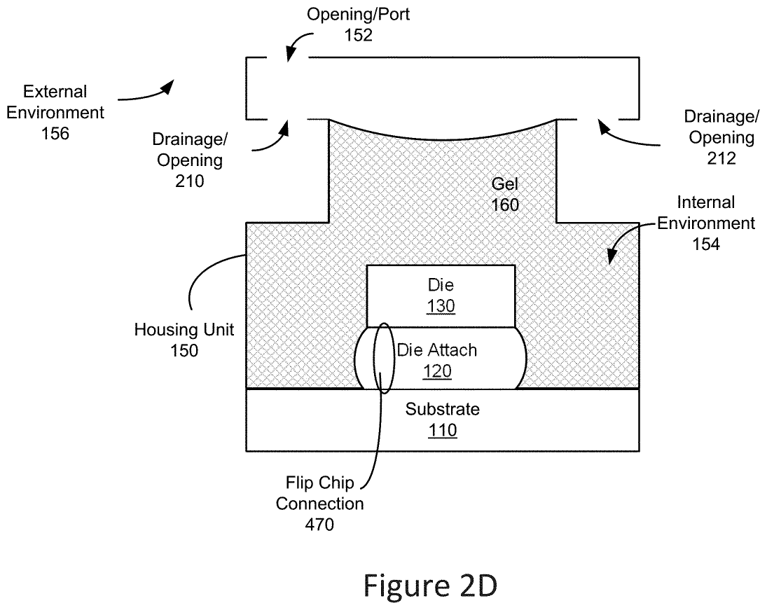

Referring now to FIGS. 2A-2D, a sensor device with a horizontal drainage mechanism in accordance with some embodiments is shown. FIG. 2A is substantially similar to that of FIG. 1B. In this embodiment, however, the housing unit 150 includes a drainage or opening 210. The drainage or opening 210 enables any liquid accumulated over the surface of the gel 160 to be drained from the internal environment 154 to the external environment 156. It is appreciated that the gel may have a thickness to cover the die 130 and the electrical coupling. The drainage or opening 210 is positioned on a horizontal surface of the housing unit 150. It is appreciated that the drainage or opening 210 enables gravity to remove the liquid accumulated on the surface of the gel 160. It is appreciated that the drainage or opening 210 may be a hole, opening, or it may have a meshed like structure. The drainage or hole 210 may have any configuration shape, e.g., circular, rectangular, elliptical, etc. It is appreciated that the drainage or hole 210 may be positioned at a lowest liquid collection point and the substrate 150.

It is appreciated that in this embodiment, the opening/port 152 may be removed because the drainage or opening 210 exposes the die 130 to the external environment 156 of the device while it also serves as a mechanism to drain the unwanted liquid accumulated over the surface of the gel 160 from the internal environment 154 to the external environment 156. It is appreciated that the embodiments of FIGS. 2A-2D and subsequent drawings are described with respect to flip connection 470. However, it is appreciated the embodiments are equally applicable to other types of connections, e.g., wire bond connection, as described with respect to FIG. 1A. As such, the description with respect to flip chip connection is for illustrative purposes and should not be construed as limiting the scope of the embodiments.

Referring now to FIG. 2B, a second drainage or opening 212 is shown in addition to the primary drainage or opening 210. The second drainage or opening 212 is substantially similar to that of drainage or opening 210, as described above. Referring now to FIG. 2C, a device similar to that of FIG. 2A is shown except that in this embodiment the housing unit 150 includes the opening/port 152, as described with respect to FIG. 1A. Referring now to FIG. 2D, a device similar to that of FIG. 2C is shown except that in this embodiment, a secondary drainage/opening 212 is also used, similar to that of FIG. 2B. It is appreciated that the number of drainage used is for illustrative purposes only and should not be construed to limit the scope of the embodiments. Furthermore, it is appreciated that the shape of the housing unit 150, as shown, is for illustrative purposes and should not be construed as limiting the scope of the embodiments. For example, the housing unit 150 may have asymmetric recess(s) such that the horizontal drainage 210 and/or 212 may be positioned on one side of the housing unit 150. Furthermore, the housing unit 150 may have multiple recesses at least on one side and have multiple drainages on one side. As such, the shape of the housing unit 150 and the positioning of the drainage 210 or 212 as well as the number of drainages are for illustrative purposes only and should not be construed as limiting the scope of the embodiments.

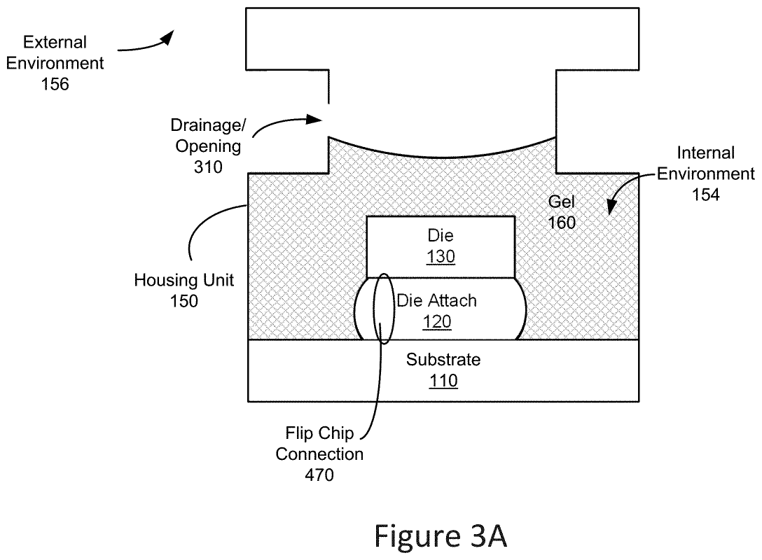

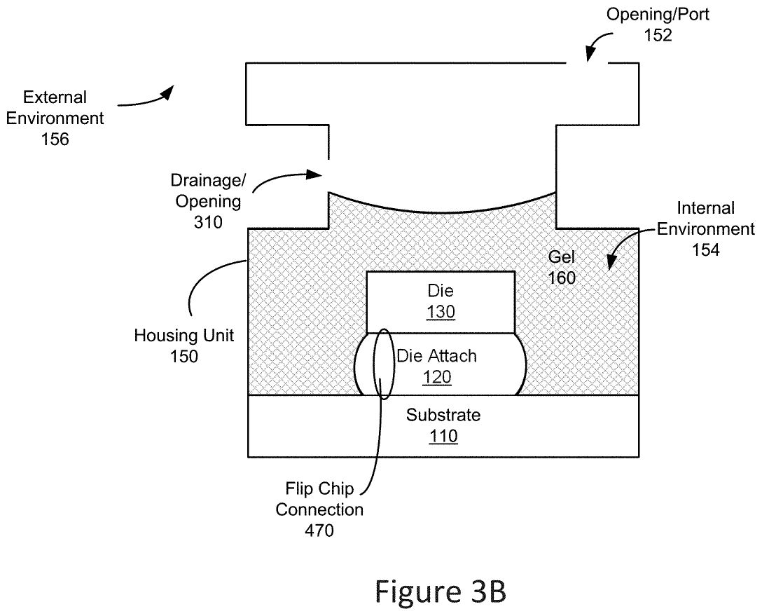

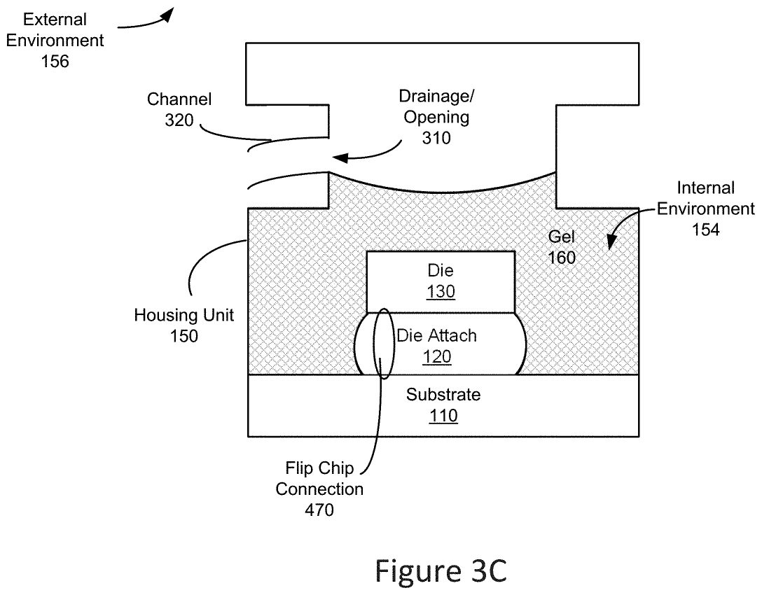

FIGS. 3A-3C show a sensor device with a vertical drainage mechanism in accordance with some embodiments. Referring specifically to FIG. 3A, the device similar to FIG. 2A is shown. In FIG. 3A, the housing unit 150 includes a drainage or opening 310 that is positioned on a vertical wall of the housing unit 150. The drainage or opening 310 functions substantially similar to that of FIGS. 2A-2D. Referring now to FIG. 3B, the opening/port 152 may also be used in addition to the drainage or opening 310, similar to that of FIG. 2C. Referring now to FIG. 3C, the device similar to FIG. 3A is shown. In this embodiment, the drainage or opening 310 further includes a channel 320 that channels the unwanted liquid from the internal environment 154 to the external environment 156.

As discussed above, it is appreciated that the shape of the housing unit 150, as shown, is for illustrative purposes and should not be construed as limiting the scope of the embodiments. The number of vertical drainage shown is for illustrative purposes and should not be construed as limiting the scope. Moreover, a combination of vertical and/or horizontal drainages may be used. As such, the shape of the housing unit 150 and the positioning of the drainage 310 and the number of drainages is for illustrative purposes only and should not be construed as limiting the scope of the embodiments.

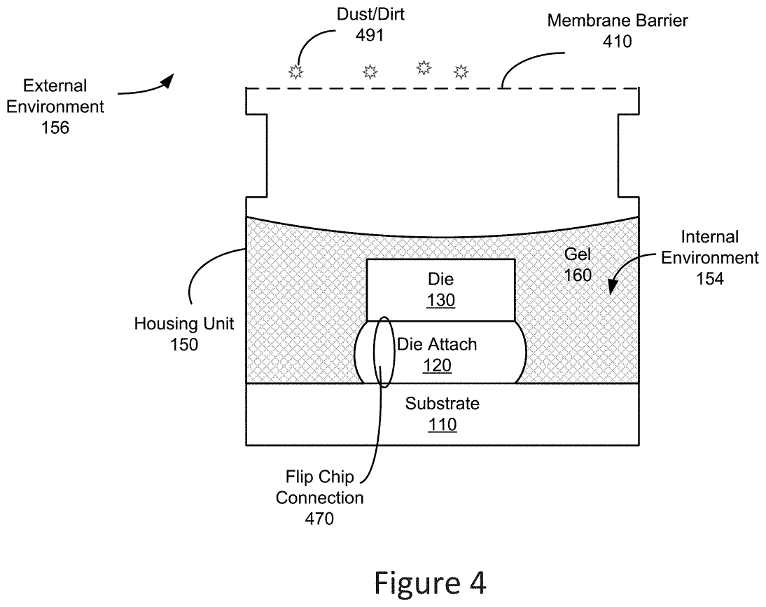

Referring now to FIG. 4, a sensor device with a membrane barrier in accordance with some embodiments. FIG. 4 is substantially similar to that of FIG. 1A. In this embodiment, the housing unit 150 may include a membrane barrier 410. The membrane barrier 410 may be porous and it may be ePTFE. The membrane barrier 410 may be a polyimide with structured holes in some embodiments. The membrane barrier 410 prevents unwanted liquid from entering the internal environment 154 of the housing unit 150 from the external environment 156. In some embodiments, the membrane barrier 410 may further prevent dust/dirt 491 from entering the internal environment 154 of the housing 150 from the external environment 156. It is appreciated that in some embodiments, the membrane barrier 410 may be positioned and designed into gasket interface or printed circuit board (PCB) to gasket interface.

It is appreciated that in some embodiments, the port or opening 152 may be removed because the membrane barrier 410 may be used to expose the sensor die 130 to the external environment 156 while it prevents the internal environment 154 from unwanted liquid exposure. However, it is appreciated that in some embodiments, the membrane barrier 410 may be positioned over the opening/port 152 (not shown) in order to enable the die 130 to be exposed to the external environment 156 while protecting the internal environment 154 from unwanted liquid. It is further appreciated that in some embodiments, a gasket interface or PCB to gasket interface may be used to reduce the amount of unwanted liquid accumulation.

While the embodiments have been described and/or illustrated by means of particular examples, and while these embodiments and/or examples have been described in considerable detail, it is not the intention of the Applicants to restrict or in any way limit the scope of the embodiments to such detail. Additional adaptations and/or modifications of the embodiments may readily appear to persons having ordinary skill in the art to which the embodiments pertain, and, in its broader aspects, the embodiments may encompass these adaptations and/or modifications. Accordingly, departures may be made from the foregoing embodiments and/or examples without departing from the scope of the concepts described herein. The implementations described above and other implementations are within the scope of the following claims.

What is claimed is:

1. A device comprising:
a sensor die;
an electrical coupling;
a substrate, wherein the sensor die is coupled to the substrate via the electrical coupling; and
a housing unit, wherein the housing unit and the substrate are configured to house the sensor die and the electrical coupling, and wherein the housing unit comprises an opening that exposes the sensor die to an environment external to the housing unit, and wherein the housing unit further comprises a drainage configured to drain liquid out from an interior environment of the housing unit to the environment external to the housing unit.

2. The device of claim 1 further comprising a gel filled within the interior environment of the housing unit covering the sensor die and the substrate, wherein the gel is configured to protect the sensor die, the electrical coupling, and the substrate from exposure to the liquid.

3. The device of claim 2, wherein the drainage is configured to drain the liquid deposited over the gel surface.

4. The device of claim 2, wherein the gel is selected from a group consisting of silicone and fluoro silicone.

5. The device of claim 2, wherein the gel is thick enough to cover the sensor die and the electrical coupling.

6. The device of claim 1, wherein the drainage is positioned on a horizontal wall of the housing unit that is positioned at a lowest liquid collection point.

7. The device of claim 1, wherein the drainage is positioned on a vertical wall of the housing unit that is positioned at a lowest liquid collection point.

8. The device of claim 7 further comprising a channel connected to the drainage to channel the liquid out from the interior environment of the housing unit to the environment external to the housing unit.

9. The device of claim 1, wherein the sensor die comprises an integrated micro-electro-mechanical system (MEMS) and a complementary metal-oxide-semiconductor (CMOS).

10. The device of claim 1, wherein the sensor die is a pressure sensor.

11. A device comprising:
a sensor die;
an electrical coupling;
a substrate, wherein the sensor die is coupled to the substrate via the electrical coupling; and
a housing unit, wherein the housing unit and the substrate are configured to house the sensor die and the electrical coupling, and wherein the housing unit comprises a membrane barrier that exposes the sensor die to an environment external to the housing unit, and wherein the membrane barrier is further configured to prevent liquid from the environment external to the housing unit to enter an interior environment of the housing unit.

12. The device of claim 11 further comprising a gel filled within the interior environment of the housing unit covering the sensor die and the substrate, wherein the gel is configured to protect the sensor die, the electrical coupling, and the substrate from exposure to the liquid.

13. The device of claim 12, wherein the gel is selected from a group consisting of silicone and fluoro silicone.

14. The device of claim 12, wherein the gel is thick enough to cover the sensor die and the electrical coupling.

15. The device of claim 11, wherein the membrane barrier is porous.

16. The device of claim 15, wherein the membrane barrier is ePTFE.

17. The device of claim 11 further comprising a drainage within the housing that is configured to drain liquid out from the interior environment of the housing unit to the environment external to the housing unit.

18. The device of claim 11, wherein the sensor die comprises an integrated micro-electro-mechanical system (MEMS) and a complementary metal-oxide-semiconductor (CMOS).

19. The device of claim 11, wherein the sensor die is a pressure sensor.

20. The device of claim 19, wherein the liquid is selected from a group consisting of water and oil.

21. The deice of claim 11, wherein the membrane barrier is a polyimide with structured holes.
